(19) United States
(12) Patent Application Publication
(10) Pub. No.: US 2015/0021716 A1
(43) Pub. Date: Jan. 22, 2015

(54) LOW POWER MICRO SEMICONDUCTOR GAS SENSOR AND METHOD OF MANUFACTURING THE SAME

(71) Applicant: Electronics and Telecommunications Research Institute, Daejeon (KR)

(72) Inventors: Dae-Sik LEE, Daejeon (KR); Moon Youn JUNG, Daejeon (KR); Seunghwan KIM, Daejeon (KR)

(73) Assignee: Electronics and Telecommunications Research Institute, Daejeon (KR)

(21) Appl. No.: 14/271,808

(22) Filed: May 7, 2014

(30) Foreign Application Priority Data
Jul. 19, 2013 (KR) 10-2013-0085557

(51) Int. Cl. G01N 27/403; H01L 21/283

(52) U.S. Cl. CPC G01N 27/403; H01L 21/283
USPC 257/414; 438/49

(57) ABSTRACT

Provided are a low power micro semiconductor gas sensor and a method of manufacturing the same. The micro semiconductor gas sensor includes a substrate having an air gap, a peripheral portion provided on the substrate and comprising electrode pads, a sensor portion comprising sensing electrodes connected from the electrode pads and a sensing film on the sensing electrodes and floating on the air gap, and a connection portion comprising conductive wires electrically connecting the electrode pads and the sensing electrodes to each other, and connecting the peripheral portion and the sensor portion to one another. In this case, the air gap penetrates the substrate, and a thermal isolation area extended from the air gap to a space between the peripheral portion and the sensor portion is provided.

### CROSS-REFERENCE TO RELATED APPLICATIONS

This U.S. non-provisional patent application claims priority under 35 U.S.C. §119 to Korean Patent Application No. 10-2013-0085557, filed on Jul. 19, 2013, the entire contents of which are hereby incorporated by reference.

### BACKGROUND OF THE INVENTION

Embodiments of the present inventive concepts relate to micro semiconductor gas sensors and method of manufacturing the micro semiconductor gas sensors.

Gas sensors have been applied to the fields of drunkometers, environment monitors, toxic gas detectors, etc. Among gas sensor driven in various manners, semiconductor gas sensors are driven using a theory, in which a change in electric resistance occurs when gas components are adsorbed on a surface of a semiconductor or react with other adsorptive gases previously adsorbed. The change in electric resistance is generated due to changes in electric conductivity and surface potential of the semiconductor. Also, a degree of the change varies with the intensity of a gas to be detected and temperature and humidity when measuring.

Semiconductor gas sensors, compared with general optical gas sensors or electrochemical gas sensors, have simple configurations and are easily manufactured, thereby allowing mass production. Also, since having small sizes and consuming small power, semiconductor gas sensors may be provided as miniaturized portable devices. Accordingly, semiconductor gas sensors may be applied to various services such as ubiquitous health monitoring. Merely, since membrane thin films used to manufacture semiconductor gas sensors having small sizes are under a lot of thermal stress while semiconductor gas sensors are operating, there is a limitation in maintaining mechanical stability of membranes. Also, in order to obtain reliable sensitivity of semiconductor gas sensors, it is necessary reduce a thermal gradient of membranes.

### SUMMARY OF THE INVENTION

The present invention provides a micro semiconductor gas sensor having membranes with improved thermal stability and a method of manufacturing the micro semiconductor gas sensor.

The present invention also provides a micro semiconductor gas sensor capable of being driven consuming small power and a method of manufacturing the micro semiconductor gas sensor.

Embodiments of the present invention provide micro semiconductor gas sensors including a substrate having an air gap, a peripheral portion provided on the substrate and including electrode pads, a sensor portion including sensing electrodes connected from the electrode pads and a sensing film on the sensing electrodes and floating on the air gap, and a connection portion including conductive wires electrically connecting the electrode pads and the sensing electrodes to each other, and connecting the peripheral portion and the sensor portion to one another, in which the air gap penetrates the substrate, and extends to a thermal isolation area where is a space between the peripheral portion and the sensor portion.

In some embodiments, the connection portion may include one or more cantilever shapes having sidewalls defined by the thermal isolation area and extended from the peripheral portion.

In other embodiments, the peripheral portion, sensor portion, and connection portion may further include a first membrane, second membrane, and third membrane sequentially deposited, and the first, second, and third membranes may include at least one of a silicon oxide film and silicon nitride film.

In still other embodiments, the sensor portion may further include a heating resistor on the second membrane, the sensing electrodes may be provided on the second membrane, the third membrane may cover the heating resistor while exposing the sensing electrodes, and the sensing film may be provided on the third membrane and electrically connected to the exposed sensing electrodes.

In even other embodiments, the sensor portion may further include a heat dispersion film provided between the first membrane and second membrane.

In yet other embodiments, the sensor portion may further include a temperature sensor provided between the second membrane and third membrane.

In further embodiments, the heating resistor may include at least one of platinum (Pt), gold (Au), tungsten (W), palladium (Pd), silicon (Si), a silicon alloy, and conductive metal oxide.

In still further embodiments, the sensor portion may further include a heating resistor between the first membrane and second membrane, the sensing electrodes are provided on the second membrane, the third membrane exposes the sensing electrodes, and the sensing film is provided on the third membrane and electrically connected to the exposed sensing electrodes.

In even further embodiments, the sensor portion may further include a temperature sensor provided between the first membrane and second membrane.

In yet further embodiments, the substrate may include at least one of aluminum oxide (Al₂O₃), glass, quartz, gallium arsenide (GaAs), and gallium nitride (GaN).

In much further embodiments, the sensing electrodes may include at least one of Pt, Au, W, Pd, Si, a silicon alloy, and conductive metal oxide.

In still much further embodiments, the sensing film may include at least one of metal oxide, nanoparticles of Au, graphene, carbon nanotubes, fullerene, and molybden disulphide (MoS₂).

In other embodiments of the present invention, methods of manufacturing a micro semiconductor gas sensor include sequentially forming a first preliminary membrane and second preliminary membrane on a substrate, forming sensing electrodes on the second preliminary membrane, forming a third preliminary membrane having openings exposing the sensing electrodes on the second preliminary membrane, forming an air gap exposing a bottom surface of the first preliminary membrane by etching the substrate below the sensing electrodes, forming first, second, and third membranes including a thermal isolation area which is extended from the air gap and penetrates the first, second, and third preliminary membranes, and forming a sensing film electrically connected to the sensing electrodes through the openings on the third membrane.

In some embodiments, the method may further include forming a heating resistor between the second preliminary membrane and third preliminary membrane.

In other embodiments, the method may further include forming a heat dispersion film between the first preliminary membrane and second preliminary membrane.

In still other embodiments, the method may further include forming a temperature sensor between the second preliminary membrane and third preliminary membrane.

In even other embodiments, the method may further include forming a heating resistor between the first preliminary membrane and second preliminary membrane.

In yet other embodiments, the method may further include forming a temperature sensor between the first preliminary membrane and second preliminary membrane.

In further embodiments, the first, second, and third preliminary membranes may be formed of at least one of a silicon oxide film and silicon nitride film.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a perspective view of a micro semiconductor gas sensor according to an embodiment of the present invention;

FIG. 2 is a top view of the micro semiconductor gas sensor of FIG. 1;

FIG. 3 is a cross-sectional view illustrating a part taken along a line I-I′ shown in FIG. 2;

FIGS. 4 to 11 are cross-sectional views illustrating a method of manufacturing a micro semiconductor gas sensor according to an embodiment of the present invention;

FIG. 12 is a perspective view of a micro semiconductor gas sensor according to another embodiment of the present invention; and

FIG. 13 is an enlarged cross-sectional view of a sensor portion for a micro semiconductor gas sensor according to still another embodiment of the present invention.

### DETAILED DESCRIPTION OF PREFERRED EMBODIMENTS

Hereinafter, exemplary embodiments of the present invention will be described in detail with reference to the attached drawings. Advantages and features of the inventive concept and a method of achieving the same will be specified with reference to the embodiments that will be described together with the attached drawings. However, the present invention is not limited to the embodiments described below and may have variously modified forms. The embodiments that will be described hereafter are provided to allow the disclosure to be thoroughgoing and perfect and to allow a person with an ordinary skill in the art to fully understand the scope of the present invention. The present invention is defined only by the scope of following claims. Throughout the entire specification, like reference numerals designate like elements.

Terms used in the specification are to describe the embodiments but not to limit the scope of the present invention. As used herein, the singular forms are intended to include the plural forms as well, unless the context clearly indicates otherwise. It will be further understood that the terms “comprises” and/or “comprising” used herein specify the presence of stated components, operations, and/or elements thereof, but do not preclude the presence or addition of one or more other components, operations, and/or elements thereof. Also, as just exemplary embodiments, reference numerals shown according to an order of description are not limited to the order. It will be understood that when a layer is referred to as being “formed on,” another layer or a substrate, it can be directly or indirectly formed on the other layer or the substrate. That is, for example, intervening layers may be present.

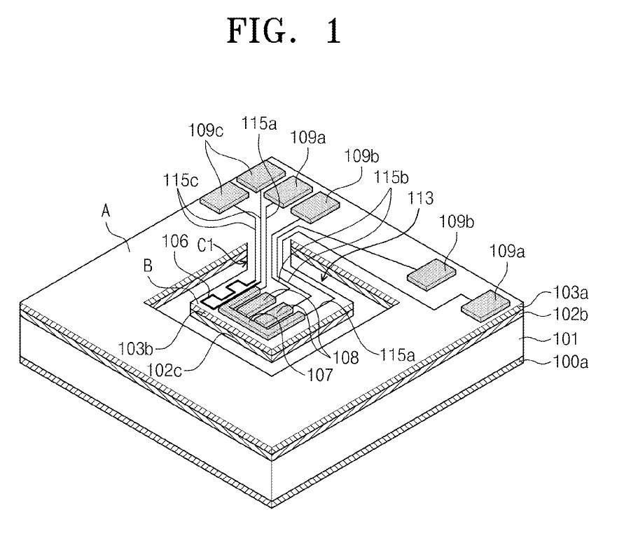

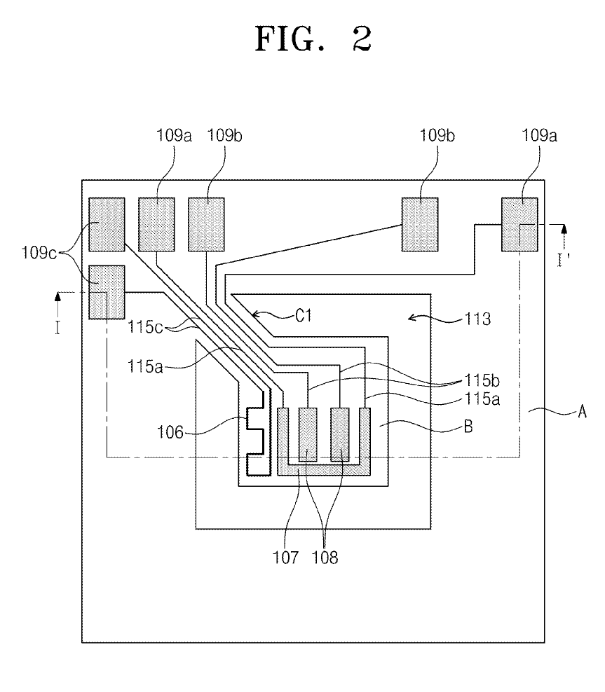

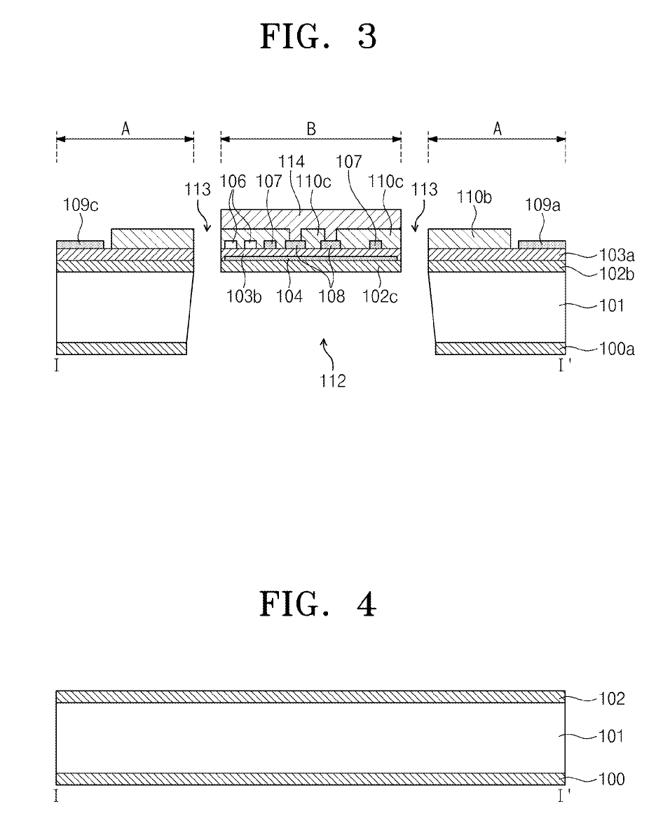

FIG. 1 is a perspective view of a micro semiconductor gas sensor according to an embodiment of the present invention. FIG. 2 is a top view of the micro semiconductor gas sensor of FIG. 1. FIG. 3 is a cross-sectional view illustrating a part taken along a line I-I′ shown in FIG. 2. In FIGS. 1 and 2, for simplification of description, some components, for example, a heat dispersion film 104, third membranes 110b and 110c, a sensing film 114, etc. are omitted and not shown.

Referring to FIG. FIGS. 1 to 3, the micro semiconductor gas sensor may include a substrate 101 including an air gap 112. The substrate 101 may be a silicon substrate used in a general semiconductor process or may include any one of aluminum oxide (Al₂O₃), glass, quartz, gallium arsenide (GaAs), and gallium nitride (GaN). The air gap 112 may be formed by etching to allow a central portion of the substrate 101 to be penetrated. The air gap 112 is substantially an empty space filled with air. The air gap 112 may perform thermal isolation to prevent heat generated from a heater resistor 107 that will be described later from being transferred to the substrate 101 that has high heat conductivity.

A peripheral portion A may be provided on the substrate 101. The peripheral portion A may include a first membrane 102b, second membrane 103a, and third membrane 110b sequentially deposited on the substrate 101. In the embodiment, under the substrate 101, on which the peripheral portion A is provided, a fourth membrane 100a may be formed. On the second membrane 103a, a plurality of electrode pads including first electrode pads 109a, second electrode pads 109b, and third electrode pads 109c may be disposed.

On the air gap 112, a sensor portion B may be provided. The sensor portion B may float on a space filled with air, substantially empty. The sensor portion B may include a first membrane 102c and a second membrane 103b sequentially deposited. On the second membrane 103b, the heating resistor 107 and sensing electrodes 108 may be disposed. Also, on the second membrane 103b, in order to expose the sensing electrodes 108, the third membrane 110c covering the heating resistor 107 may be disposed. The third membrane 110c may electrically insulate the heating resistor 107 and the respective sensing electrodes 108 from one another. On the third membrane 110c, the sensing film 114 electrically connected to the exposed sensing electrodes 108 may be disposed.

In one embodiment, between the first membrane 102c and second membrane 103b, the heat dispersion film 104 may be disposed. Also, in another embodiment, a temperature sensor 106 may be disposed on one side of the heating resistor 107. The temperature sensor 106 may be electrically insulated from the heating resistor 107 by the third membrane 110c.

A connection portion C1 connecting the sensor portion B and the peripheral portion A to each other may be provided. The connection portion C1 may include a first membrane, second membrane, and third membrane sequentially deposited. Also, the connection portion C1 may include first conductive wires 115a, second conductive wires 115b, and third conductive wires 115c. The first, second, and third wires 115a, 115b, and 115c may be disposed between the second membrane and third membrane and may be formed together with the temperature sensor 106, heating resistor 107, sensing electrodes 108, or the electrode pads 109a, 109b, and 109c. The first conductive wires 115a may electrically connect the first electrode pads 109a and the heating resistor 107 to one another. The second conductive wires 115b may electrically connect the second electrode pads 109b and the sensing electrodes 108 to one another. The third conductive wires 115c may electrically connect the third electrode pads 109c and the temperature sensor 106 to one another.

A thermal isolation area 113 extended from the air gap 112 to a space between the peripheral portion A and the sensor portion B may be provided. The thermal isolation area 113 is a substantially empty space filled with air. Since being filled with air whose permittivity is lower than the first, second, and third membranes 102b, 102c, 103b, and 110c, the thermal isolation area 113 has low heat conductivity. Accordingly, the thermal isolation area 113 surrounds the sensor portion B, thereby reducing a loss of heat generated from the heating resistor 107 toward the peripheral portion A. Also, the mass of the membranes 102c, 103b, and 110c mechanically supporting the heating resistor 107 is reduced, thereby decreasing power consumption for heating.

The connection portion C1 may have the shape of a cantilever having sidewalls defined by the thermal isolation area 113 and extended from the peripheral portion A.

The membranes 100a, 102b, 102c, 103a, 103b, 110b, and 110c may be formed of one of silicon compounds and a combination thereof, in order to decrease heat conductivity and to relieve thermal stresses. For example, the first, second, third, and fourth membranes 100a, 102b, 102c, 103a, 103b, 110b, and 110c may include at least one of silicon oxide and silicon nitride. As an example, the membranes 100a, 102b, 102c, 103a, 103b, 110b, and 110c may have a single layer structure of one of silicon oxide and silicone nitride or a multilayer structure of one of silicon nitride/silicon oxide/silicon nitride and silicon oxide/silicon nitride/silicon oxide. A configuration ratio of thicknesses of a single or plurality of silicon compounds may be designed in order to reduce a deformation caused by thermal stress.

The heating resistor 107 may include at least one of platinum (Pt), gold (Au), tungsten (W), palladium (Pd), silicon (Si), a silicon alloy, and conductive metal oxide. Generally, since a semiconductor gas sensor operates at 300° C. , it is necessary to increase a temperature. The heating resistor 107 generates Joule heat using power externally applied, thereby operating as a heater. The heating resistor 107 generates heat using the power externally applied, to increase a temperature to a certain degree to allow the micro semiconductor gas sensor to have optimum sensitivity.

The temperature sensor 106 may be formed of a material identical to the heating resistor 107. That is, the temperature sensor 106 may include at least one of Pt, Au, W, Pd, Si, a silicon alloy, and conductive metal oxide. The temperature sensor 106 measures a temperature of the heating resistor 107 to allow the temperature of the heating resistor 107 to be controlled.

The heat dispersion film 104 may include one of a metal having high heat conductivity and doped silicon. The heat dispersion film 104 may uniformly disperse the heat generated from the heating resistor 107 in the sensor portion B.

The sensing electrodes 108 may include at least one of Pt, Au, W, Pd, Si, a silicon alloy, and conductive metal oxide. The sensing electrodes 108 may transmit a change of a resistance value occurring as the sensing film 114 adsorbs a gas to an external circuit (not shown).

The plurality of electrode pads 109a, 109b, and 109c and the plurality of conductive wires 115a, 115b, and 115c may be formed of the same material by using the same method as the heating resistor 107 and sensing electrodes 108.

The sensing film 114 may include at least one of metal oxide, nanoparticles of Au, graphene, carbon nanotubes, fullerene, and molybden disulphide (MoS2). As an example, the metal oxide may be formed of a combination of two or more of tungsten oxide (WOₓ), an oxide of tin (SnOₓ), zinc oxide (ZnOₓ), indium oxide (InOₓ), titanium oxide (TiOₓ), gallium oxide (GaOₓ), and cobalt oxide (CoOₓ) with a certain ratio. In another embodiment, the metal oxide may further include, as auxiliary particles, at least one metal of Pt, Au, W, and Pd or metal oxide such as aluminum oxide (Al₂O₃).

The metal oxide may be nanoparticles whose average diameter is from about 1 nm to about 500 nm. Also, the metal oxide may have a thin film having a columnar structure formed as a nanocolumn. Since the nanoparticles may increase in a contact force with the sensing electrodes 108, a change in electric resistance, caused by a gas in contact with the sensing film 114, may be more sensitively checked. Also, since the nanoparticles have a large surface area and are changed greatly by external effects, an operation temperature of the micro semiconductor gas sensor may be greatly decreased.

The micro semiconductor gas sensor may be operated as follows. As an example, when components of a gas such as COₓ or SOₓ (herein, x is a constant) are in contact with the micro semiconductor gas sensor, the gas is adsorbed onto the sensing film 114. According thereto, electrons move in proportion to an amount of the gas adsorbed on the sensing film 114. In this case, since a potential barrier is formed against electronic conduction on a grain boundary of the sensing film 114 and obstructs the movement of the electrons, a resistance value of the sensing film 114 becomes changed. Accordingly, when measuring the resistance value of the sensing film 114, the density and presence of the gas may be detected.

The micro semiconductor gas sensor is formed with the thermal isolation area 113 around the sensor portion B, on which the heating resistor 107 is disposed, thereby reducing a loss of the heat generated by the heating resistor 107. Also, the mass of the membranes 102c, 103b, and 110c supporting the sensor portion B is minimized, thereby increasing a temperature to a certain degree by consuming small power. Also, the heat dispersion film 104 having high heat conductivity is disposed below the second membrane 103b, on which the heating resistor 107 is disposed, thereby uniformly dispersing the heat generated by the heating resistor 107 in the membranes 102c, 103b, and 110c. In addition, the membranes 102c, 103b, and 110c are formed of a single or a plurality of silicon compounds to minimize thermal stress, thereby improving mechanical stability of the membranes 102c, 103b, and 110c. Accordingly, it is possible to provide a micro semiconductor gas sensor consuming small power and having improved mechanical stability.

FIGS. 4 to 11 are cross-sectional views illustrating a method of manufacturing the micro semiconductor gas sensor according to an embodiment of the present invention.

Referring to FIG. 4, a first preliminary membrane 102 and a fourth preliminary membrane 100 may be formed on a top and bottom surface of the substrate 101. The substrate 101 may be a silicon substrate used in a general semiconductor process or may include any one of Al₂O₃, glass, quartz, GaAs, and GaN.

The first and fourth preliminary membranes 102 and 100 may be formed of one of silicon compounds or a combination thereof, in order to decrease heat conductivity and relieve thermal stresses. As an example, the first and fourth preliminary membranes 102 and 100 may include at least one of a silicon oxide film and silicon nitride film. As an example, the first and fourth preliminary membranes 102 and 100 may have a single structure formed of one of a silicon oxide and silicon nitride or a multilayer structure formed of one of silicon nitride/silicon oxide/silicon nitride and silicon oxide/silicon nitride/silicon oxide. A configuration ratio of thicknesses of a single or plurality of silicon compounds may be designed in order to reduce a deformation caused by thermal stress. The first and fourth preliminary membranes 102 and 100 may be formed using one of thermo-oxidative deposition, sputtering deposition, and chemical vapor deposition. The first and fourth preliminary membranes 102 and 100 may be formed at the same time.

Referring to FIG. 5, an opening 105 exposing the bottom surface of the substrate 101 may be formed by etching the fourth preliminary membrane 100. Simultaneously, the fourth membrane 100a may be formed. The etching process may be performed using one of buffered oxide etchant and vapor HF.

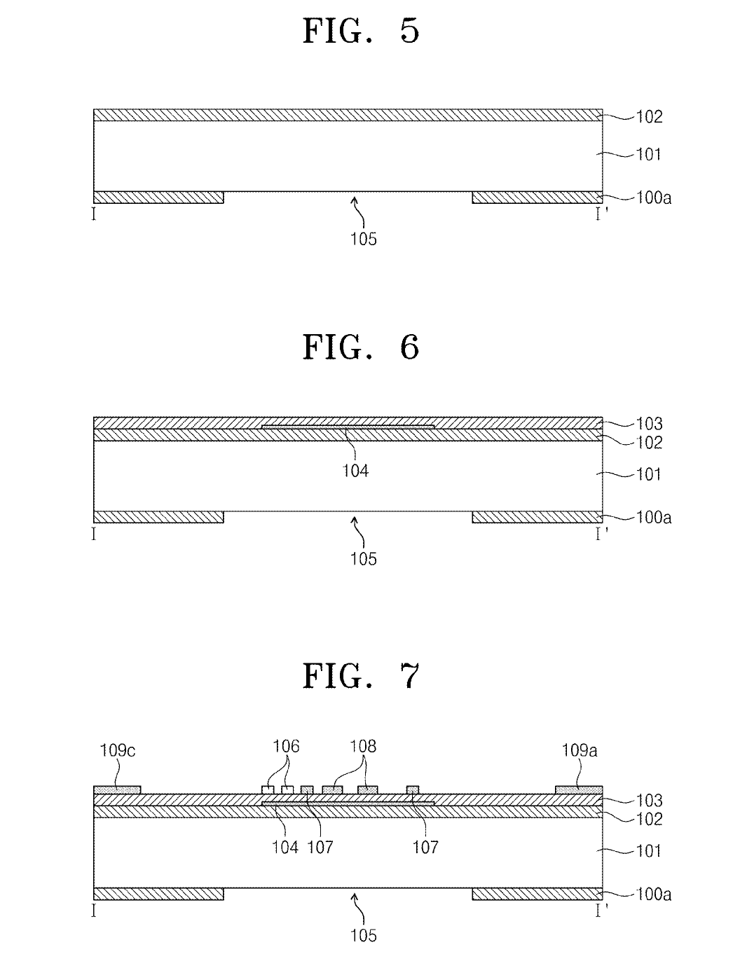

Referring to FIG. 6, metal or doped silicon having high heat conductivity is deposited on the first preliminary membrane 102 and then patterning and etching processes are performed using photolithography, thereby forming the heat dispersion film 104. After that, a second preliminary membrane 103 covering the heat dispersion film 104 may be formed on the first preliminary membrane 102. The heat dispersion film 104 may be formed using one of sputtering deposition, E-beam deposition, and evaporation. The second preliminary membrane 103 may be formed of the same material using the same method as the first preliminary membrane 102.

Referring to FIG. 7, a conductive layer including at least one of Pt, Au, W, Pd, Si, a silicon alloy, and a conductive metal oxide may be formed on the second preliminary membrane 103. The conductive layer may be formed using one of sputtering deposition, E-beam deposition, and evaporation. After that, the temperature sensor 106, the heating resistor 107, sensing electrodes 108, a plurality of electrode pads (not shown), and a plurality of conductive wires (not shown) may be formed by performing patterning and etching processes using photolithography.

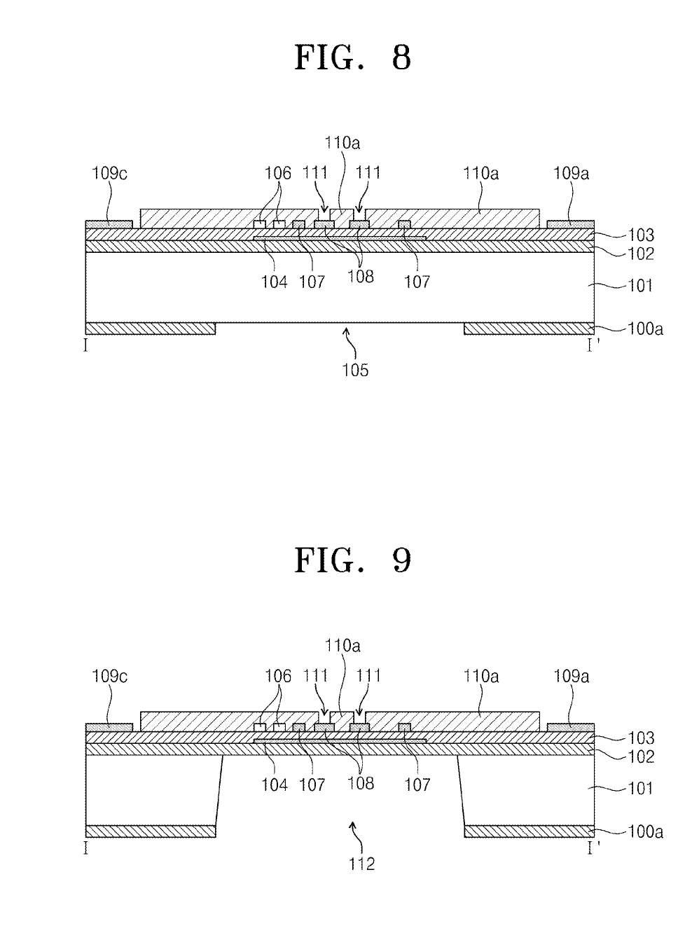

Referring to FIG. 8, an insulating film electrically insulating the heating resistor 107, sensing electrodes 108, and temperature sensor 106 from one another may be formed on the second preliminary membrane 103. The insulating film may be formed of the same material using the same method as the first preliminary membrane 102 and second preliminary membrane 103. After that, a third preliminary membrane 110a having openings 111 exposing the sensing electrodes 108 may be formed by performing patterning and etching processes using photolithography.

Referring to FIG. 9, the air gap 112 exposing a bottom surface of the first preliminary membrane 102 may be formed by bulk etching the bottom surface of the substrate 101. The etching process may use one of potassium hydroxide (KOH), tetramethylammonium hydroxide (TMAH), and deep reactive ion etching (RIE).

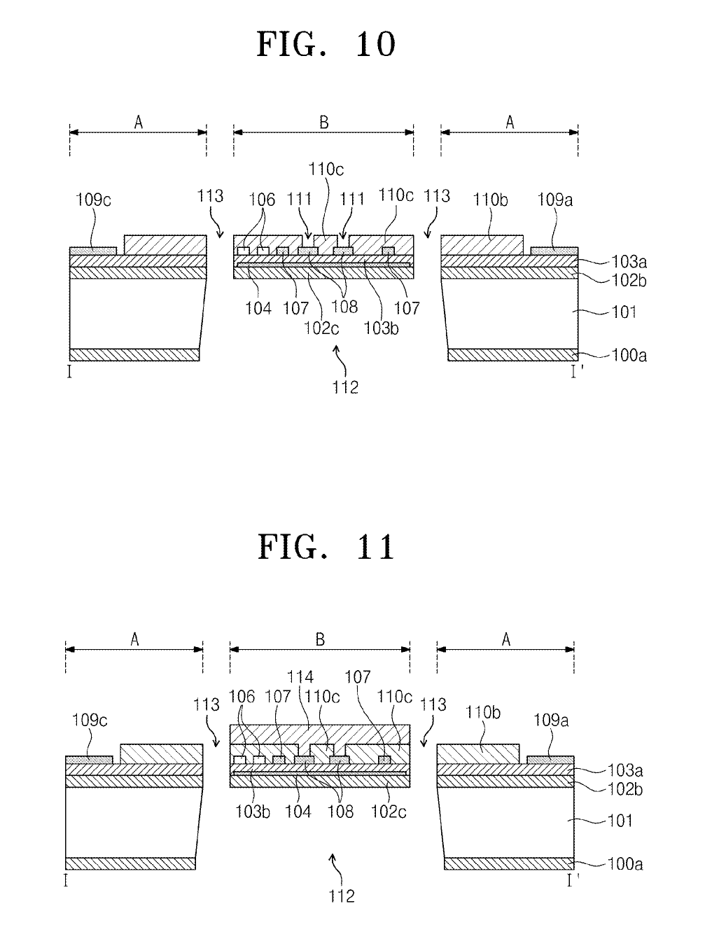

Referring to FIG. 10, the thermal isolation area 113 may be formed by etching the first, second, and third preliminary membranes 102, 103, and 110a on the air gap 112 to allow some areas thereof to be penetrated. Simultaneously, the first, second, and third membranes 102b, 102c, 103a, 103b, 110b, and 110c including the thermal isolation area 113 may be formed. In order to form the thermal isolation area 113, one of an RIE process and wet etching process may be performed.

Referring to FIG. 11, the sensing film 114 electrically connected to the sensing electrodes 108 through the openings 111 may be formed on the third membrane 110c. The sensing film 114 may include at least one of metal oxide, nanoparticles of Au, graphene, carbon nanotubes, fullerene, and MoS2. As an example, the metal oxide may be formed of a combination of two or more of WOₓ, SnOₓ, ZnOₓ, InOₓ, TiO_{N}, GaOₓ, and CoOₓ with a certain ratio. In another embodiment, the metal oxide may further include, as auxiliary particles, at least one metal of Pt, Au, W, and Pd or metal oxide such as aluminum oxide (Al₂O₃).

The metal oxide may be nanoparticles whose average diameter is from about 1 nm to about 500 nm Also, the metal oxide may have a thin film having a columnar structure formed as a nanocolumn. Since the nanoparticles may increase in a contact force with the sensing electrodes 108, a change in electric resistance, caused by a gas in contact with the sensing film 114, may be more sensitively checked. Also, since a sensing material for the nanoparticles has a large surface area and is changed greatly by an external effect, an operation temperature of the micro semiconductor gas sensor may be greatly decreased.

The sensing film 114 may be formed using one of a sol-gel process, drop coating process, screen printing process, sputtering deposition, and chemical vapor deposition. Particularly, the sensing film 114 including the sensing material of the nanoparticles may be formed using one of contact printing, nanoimplanting, and drop dispensing.

According to the method of manufacturing the micro semiconductor gas sensor, gas sensors having shapes of capable of minimizing a loss of heat generated from a heating resistor may be produced in large quantities using a bulk micromachining process. Also, membranes are designed to minimize deformations caused by thermal stresses, thereby improving mechanical stability of heated membranes. Accordingly, it is possible to manufacture low power micro semiconductor gas sensors miniaturized to be used in a ubiquitous environment in large quantities at low cost.

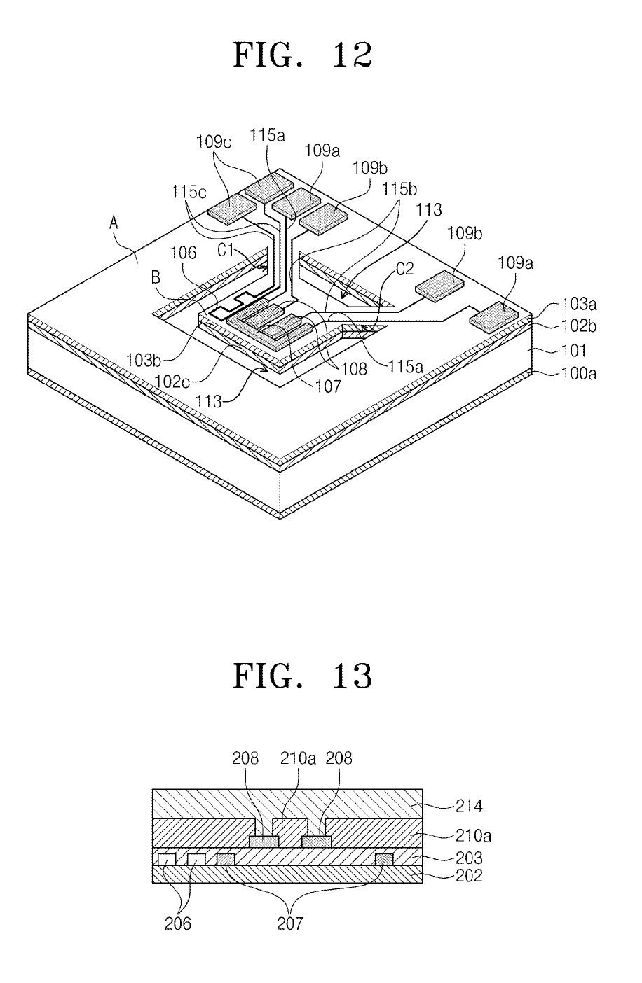

FIG. 12 is a perspective view of a micro semiconductor gas sensor according to another embodiment of the present invention. For simplification of description, a description of a repetitive configuration will be omitted.

Referring to FIG. 12, the micro semiconductor gas sensor may include two connection portions C1 and C2. That is, the micro semiconductor gas sensor may include the connection portions C1 and C2 having a cantilever shape extended from the peripheral portion A to connect the peripheral portion A and the sensor portion B to each other. Through this, mechanical stability of the sensor portion B may be improved. Although not shown in the drawings, the micro semiconductor gas sensor of FIG. 12 may include three or more connection portions.

FIG. 13 is an enlarged cross-sectional view of a sensor portion for a micro semiconductor gas sensor according to still another embodiment of the present invention. For simplification of description, a description of a repetitive configuration will be omitted.

Referring to FIG. 13, a sensor portion of the micro semiconductor gas sensor may include a first membrane 202 and a heating resistor 207 on the first membrane 202. A second membrane 203 covering the heating resistor 207 may be disposed on the first membrane 202. Sensing electrodes 208 may be disposed on the second membrane 203. In another embodiment, a temperature sensor 206 may be disposed on one side of the heating resistor 207.

A third membrane 210a exposing the sensing electrodes 208 may be disposed on the second membrane 203. The third membrane 210a may electrically insulate the sensing electrodes 208 from one another. On the third membrane 210a, a sensing film 214 electrically connected to the exposed sensing electrodes 208 may be disposed.

The micro semiconductor gas sensor of FIG. 13 has a structure substantially identical to the micro semiconductor gas sensor of FIGS. 1 to 3. Merely, the temperature sensor 206, heating resistor 207, and sensing electrodes 208 are disposed on the sensor portion in a different arrangement and a heat dispersion film is not disposed. Accordingly, the membranes 202, 203, and 210a, temperature sensor 206, heating resistor 207, sensing electrodes 208, and sensing film 214 may be formed of the same material using the same method as the membranes 100a, 102b, 102c, 103a, 103b, 110b, and 110c, temperature sensor 106, heating resistor 107, sensing electrodes 108, and sensing film 114 of FIGS. 1 to 3. Although not shown in the drawings, a plurality of electrode pads and a plurality of conductive wires of the micro semiconductor gas sensor of FIG. 13, only different in arrangement, may be formed of the same material using the same method as the electrode pads 109a, 109b, and 109c and conductive wires 115a, 115b, and 115c of FIGS. 1 to 3.

As described above, according to the embodiments, a thermal isolation area is formed around a sensor portion, on which a heating resistor is disposed, thereby reducing a loss of heat generated by the heating resistor. Also, the mass of membranes supporting the sensor portion is minimized, thereby increasing a temperature to a certain degree consuming small power. Also, a heat dispersion film having high heat conductivity is disposed below a second membrane, on which the heating resistor is disposed, thereby uniformly dispersing the heat generated by the heating resistor on the membranes. In addition, the membranes are formed of a single or a plurality of silicon compounds in order to minimize thermal stress, thereby providing a micro semiconductor gas sensor having improved mechanical stability of the heated membranes.

Accordingly, it is possible to provide a micro semiconductor gas sensor miniaturized to be used in a ubiquitous environment, consuming small power, and having improved mechanical stability and a method of manufacturing the micro semiconductor gas sensor in large quantities at low cost.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A micro semiconductor gas sensor comprising:
a substrate having an air gap;
a peripheral portion provided on the substrate and comprising electrode pads;
a sensor portion comprising sensing electrodes connected from the electrode pads and a sensing film on the sensing electrodes, and floating on the air gap; and
a connection portion comprising conductive wires electrically connecting the electrode pads and the sensing electrodes to each other and connecting the peripheral portion and the sensor portion to one another,
wherein the air gap penetrates the substrate, and extends to a thermal isolation area where is a space between the peripheral portion and the sensor portion.

2. The micro semiconductor gas sensor of claim 1, wherein the connection portion comprises one or more cantilever shapes having sidewalls defined by the thermal isolation area and extended from the peripheral portion.

3. The micro semiconductor gas sensor of claim 1, wherein the peripheral portion, the sensor portion, and the connection portion further comprise a first membrane, second membrane, and third membrane sequentially deposited, and
wherein the first, second, and third membranes comprise at least one of a silicon oxide film and silicon nitride film.

4. The micro semiconductor gas sensor of claim 3, wherein the sensor portion further comprises a heating resistor on the second membrane,
wherein the sensing electrodes are provided on the second membrane,
wherein the third membrane covers the heating resistor while exposing the sensing electrodes, and
wherein the sensing film is provided on the third membrane and electrically connected to the exposed sensing electrodes.

5. The micro semiconductor gas sensor of claim 4, wherein the sensor portion further comprises a heat dispersion film provided between the first membrane and second membrane.

6. The micro semiconductor gas sensor of claim 4, wherein the sensor portion further comprises a temperature sensor provided between the second membrane and third membrane.

7. The micro semiconductor gas sensor of claim 4, wherein the heating resistor comprises at least one of platinum (Pt), gold (Au), tungsten (W), palladium (Pd), silicon (Si), a silicon alloy, and conductive metal oxide.

8. The micro semiconductor gas sensor of claim 3, wherein the sensor portion further comprises a heating resistor between the first membrane and second membrane,
wherein the sensing electrodes are provided on the second membrane,
wherein the third membrane exposes the sensing electrodes, and
wherein the sensing film is provided on the third membrane and electrically connected to the exposed sensing electrodes.

9. The micro semiconductor gas sensor of claim 8, wherein the sensor portion further comprises a temperature sensor provided between the first membrane and second membrane.

10. The micro semiconductor gas sensor of claim 1, wherein the substrate comprises at least one of aluminum oxide (Al₂O₃), glass, quartz, gallium arsenide (GaAs), and gallium nitride (GaN).

11. The micro semiconductor gas sensor of claim 1, wherein the sensing electrodes comprise at least one of Pt, Au, W, Pd, Si, a silicon alloy, and conductive metal oxide.

12. The micro semiconductor gas sensor of claim 1, wherein the sensing film comprises at least one of metal oxide, nanoparticles of Au, graphene, carbon nanotubes, fullerene, and molybden disulphide (MoS₂).

13. A method of manufacturing a micro semiconductor gas sensor, comprising:
sequentially forming a first preliminary membrane and second preliminary membrane on a substrate;
forming sensing electrodes on the second preliminary membrane;
forming a third preliminary membrane having openings exposing the sensing electrodes on the second preliminary membrane;
forming an air gap exposing a bottom surface of the first preliminary membrane by etching the substrate below the sensing electrodes;
forming first, second, and third membranes comprising a thermal isolation area which is extended from the air gap and penetrates the first, second, and third preliminary membranes; and
forming a sensing film electrically connected to the sensing electrodes through the openings on the third membrane.

14. The method of claim 13, further comprising forming a heating resistor between the second preliminary membrane and third preliminary membrane.

15. The method of claim 14, further comprising forming a heat dispersion film between the first preliminary membrane and second preliminary membrane.

16. The method of claim 14, further comprising forming a temperature sensor between the second preliminary membrane and third preliminary membrane.

17. The method of claim 13, further comprising forming a heating resistor between the first preliminary membrane and second preliminary membrane.

18. The method of claim 17, further comprising forming a temperature sensor between the first preliminary membrane and second preliminary membrane.

19. The method of claim 13, wherein the first, second, and third preliminary membranes are formed of at least one of a silicon oxide film and silicon nitride film.
